(19) United States
(12) Patent Application Publication
(10) Pub. No.: US 2017/0076943 A1
(43) Pub. Date: Mar. 16, 2017

(54) OXIDE SINTERED BODY, SPUTTERING TARGET, AND OXIDE SEMICONDUCTOR THIN FILM OBTAINED USING SPUTTERING TARGET

(71) Applicant: SUMITOMO METAL MINING CO., LTD., Tokyo (JP)

(72) Inventors: Tokuyuki NAKAYAMA, Ome-shi (JP); Eiichiro NISHIMURA, Ome-shi (JP); Masashi IWARA, Ome-shi (JP)

(73) Assignee: SUMITOMO METAL MINING CO., LTD., Tokyo (JP)

(21) Appl. No.: 15/125,391

(22) PCT Filed: Mar. 9, 2015
(86) PCT No.: PCT/JP2015/056809

§ 371 Date: Sep. 12, 2016

(30) Foreign Application Priority Data
Mar. 14, 2014 (JP) 2014-052461

(51) Int. Cl. H01L 21/02; C23C 14/08; C04B 35/622; H01L 29/786; H01L 27/12; C04B 35/01; C23C 14/34; H01J 37/34

(52) U.S. Cl. CPC H01L 21/02565; C23C 14/3407; C23C 14/086; H01J 37/3426; H01L 21/02631; H01L 29/78693; H01L 27/1225; C04B 35/01; C04B 35/62218; C04B 2235/3286; C04B 2235/81; C04B 2235/80; C04B 2235/77

(57) ABSTRACT

An oxide sintered body which, when made into an oxide semiconductor thin film by sputtering, can achieve low carrier density and high carrier mobility, and a sputtering target using said oxide sintered body are provided. This oxide sintered body contains indium and gallium as oxides, contains nitrogen, and does not contain zinc. The gallium content in terms of the atomic ratio Ga/(In+Ga) is between 0.20 and 0.60, inclusive, and substantially no GaN phase is included. Furthermore, the sintered oxide preferably has no Ga₂O₃ phase. An amorphous oxide semiconductor thin film formed using this oxide sintered body as a sputtering target yields a carrier density of 3.0×10¹⁸ cm⁻³ or less, and a carrier mobility of 10 cm² V⁻¹ sec⁻¹ or more.

### TECHNICAL FIELD

The present invention relates to an oxide sintered body, a target, and an oxide semiconductor thin film obtained by using the target, and more particularly to a sputtering target that achieves reduced carrier density of an amorphous oxide semiconductor thin film when the sputtering target contains nitrogen, a nitrogen-containing oxide sintered body most suitable for obtaining the sputtering target, and a nitrogen-containing amorphous oxide semiconductor thin film that is obtained by using the sputtering target and has low carrier density and high carrier mobility.

### BACKGROUND ART

Thin film transistors (TFTs) are a type of field effect transistors (hereinafter referred to as FETs). TFTs are three-terminal elements having a gate terminal, a source terminal, and a drain terminal in the basic structure. TFTs are active elements having a function of switching the current between the source terminal and the drain terminal so that a semiconductor thin film deposited on a substrate is used as a channel layer in which electrons or holes move and a voltage is applied to the gate terminal to control the current flowing in the channel layer. TFTs are electronic devices that are most widely used these days in practical application. Typical applications of TFTs include liquid-crystal driving elements.

Currently, most widely used TFTs are metal-insulator-semiconductor-FETs (MIS-FETs) in which a polycrystalline silicon film or an amorphous silicon film is used as a channel layer material. MIS-FETs including silicon are opaque to visible light and thus fail to form transparent circuits. Therefore, when MIS-FETs are used as switching elements for driving liquid crystals in liquid crystal displays, the aperture ratio of a display pixel in the devices is small.

Due to the recent need for high-resolution liquid crystals, switching elements for driving liquid crystals now require high-speed driving. In order to achieve high-speed driving, a semiconductor thin film in which the mobility of carriers, electrons or holes, is higher than that in at least amorphous silicon needs to be used as a channel layer.

Under such circumstances, Patent Document 1 proposes a transparent semi-insulating amorphous oxide thin film which is a transparent amorphous oxide thin film deposited by vapor deposition and containing elements of In, Ga, Zn, and O. The composition of the oxide is InGaO₃(ZnO)ₘ (m is a natural number less than 6) when the oxide is crystallized. The transparent semi-insulating amorphous oxide thin film is a semi-insulating thin film having a carrier mobility (also referred to as carrier electron mobility) of more than 1 cm² V⁻¹ sec⁻¹ and a carrier density (also referred to as carrier electron density) of 10¹⁶ cm⁻³ or less without doping with an impurity ion. Patent Document 1 also proposes a thin film transistor in which the transparent semi-insulating amorphous oxide thin film is used as a channel layer.

However, as proposed in Patent Document 1, the transparent amorphous oxide thin film (a-IGZO film) containing elements of In, Ga, Zn, and O and deposited by any method of vapor deposition selected from sputtering and pulsed laser deposition has an electron carrier mobility in the range of only about from 1 to 10 cm² V⁻¹ sec⁻¹. It is pointed out that this carrier mobility is insufficient to further improve the definition of displays.

Regarding materials for solving such a problem, Patent Document 2 proposes a thin film transistor including an oxide thin film in which gallium is dissolved in indium oxide. In the oxide thin film, the Ga/(Ga+In) atomic ratio is 0.001 to 0.12, and the percentage of indium and gallium with respect to the total metal atoms is 80 at % or more. The oxide thin film has an In₂O₃ bixbyite structure. An oxide sintered body is proposed as the material of the oxide thin film in which gallium is dissolved in indium oxide. In the oxide sintered body, the Ga/(Ga+In) atomic ratio is 0.001 to 0.12, and the percentage of indium and gallium with respect to the total metal atoms is 80 at % or more. The oxide sintered body has an In₂O₃ bixbyite structure.

However, the carrier density described in Examples 1 to 8 of Patent Document 2 is at the level of 10¹⁸ cm⁻³, and there is still a problem that the carrier density is too high for the oxide semiconductor thin film to be applied to a TFT.

On the other hand, in Patent Documents 3 and 4, a sputtering target composed of an oxide sintered body which further contains nitrogen at a predetermined concentration in addition to In, Ga, and Zn is disclosed.

However, in Patent Documents 3 and 4, a compact containing indium oxide is sintered in an atmosphere which does not contain oxygen and at a temperature of 1000° C. or higher, and thus indium oxide is decomposed to produce indium. As a result, it is not possible to obtain the desired sintered oxynitride.

Patent Document 1: Japanese Unexamined Patent Application, Publication No. 2010-219538

Patent Document 2: PCT International Publication No. WO2010/032422

Patent Document 3: Japanese Unexamined Patent Application, Publication No. 2012-140706

Patent Document 4: Japanese Unexamined Patent Application, Publication No. 2011-058011

Patent Document 5: Japanese Unexamined Patent Application, Publication No. 2012-253372

Non-Patent Document 1: A. Takagi, K. Nomura, H. Ohta, H. Yanagi, T. Kamiya, M. Hirano, and H. Hosono, Thin Solid Films 486, 38(2005)

### DISCLOSURE OF THE INVENTION

### Problems to be Solved by the Invention

An object of the present invention is to provide a sputtering target which is able to lower the carrier density of an amorphous oxide semiconductor thin film by containing nitrogen but not containing zinc therein, a oxide sintered body which contains nitrogen and is optimum for obtaining the sputtering target, and an amorphous oxide semiconductor thin film which contains nitrogen is obtained by using the oxide sintered body, and has a low carrier density and a high carrier mobility.

### Means for Solving the Problems

The present inventors have performed a trial production of an oxide sintered body in which various elements are added to an oxide of indium and gallium in a trace amount. Furthermore, it has been newly found out that an amorphous oxide semiconductor thin film obtained by machining the oxide sintered body into a sputtering target and then depositing the sputtering target into a film by sputtering has the same atomic ratio as that of the oxide sintered body, favorable wet etching property, a low carrier density, and a high carrier mobility.

In particular, an important result was obtained by further including nitrogen in an oxide sintered body containing indium and gallium as oxides. That is, it was found out that (1) an amorphous oxide semiconductor thin film formed also contains nitrogen, for example, in the case of using the oxide sintered body described above as a sputtering target, which makes it possible to lower the carrier density of the heated amorphous oxide semiconductor thin film and to increase the carrier mobility thereof, (2) by not including zinc in the oxide sintered body which contains nitrogen, nitrogen is efficiently substitutionally dissolved in the lattice positions of oxygen in the bixbyite structure of the oxide sintered body as well as it is possible to increase the sintering temperature so that the density of sintered body is increased, and (3) by employing ordinary-pressure sintering in an atmosphere having a volume fraction of oxygen over 20%, nitrogen is efficiently substitutionally dissolved in the lattice positions of oxygen in the bixbyite structure of the oxide sintered body dissolved in the lattice positions as well as the density of sintered body of the oxide sintered body is increased.

That is, in a first embodiment of the present invention, an oxide sintered body includes indium and gallium as oxides, in which a gallium content is 0.20 or more and 0.60 or less in terms of Ga/(In+Ga) atomic ratio, the oxide sintered body contains nitrogen but does not contain zinc, and the oxide sintered body does not substantially include a GaN phase having a wurtzite-type structure.

In a second embodiment of the present invention, the gallium content is 0.20 or more and 0.35 or less in terms of Ga/(In+Ga) atomic ratio in the oxide sintered body according to the first embodiment.

In a third embodiment of the present invention, a density of nitrogen is 1×10¹⁹ atoms/cm³ or more in the oxide sintered body according to the first or second embodiment.

In a fourth embodiment of the present invention, the oxide sintered body according to any one of the first to third embodiments oxide sintered body is composed of an In₂O₃ phase having a bixbyite-type structure, and a GaInO₃ phase having a β-Ga₂O₃-type structure as a formed phase other than the In₂O₃ phase, or a GaInO₃ phase having a β-Ga₂O₃-type structure and a (Ga, In)₂O₃ phase as a formed phase other than the In₂O₃ phase.

In a fifth embodiment of the present invention, an X-ray diffraction peak intensity ratio of the GaInO₃ phase having a β-Ga₂O₃-type structure defined by formula 1 below is in the range of 30% or more and 98% or less in the oxide sintered body according to the fourth embodiment.

100×I[GaInO₃ phase(111)]/{I[In₂O₃ phase(400)]+I[GaInO₃ phase(111)]}[%] Formula 1

In a sixth embodiment of the present invention, the oxide sintered body according to any one of the first to fifth embodiments does not include a Ga₂O₃ phase having a β-Ga₂O₃-type structure.

In a seventh embodiment of the present invention, the oxide sintered body according to any one of the first to sixth embodiments is sintered by ordinary-pressure sintering in an atmosphere having a volume fraction of oxygen over 20%.

In an eighth embodiment of the present invention, a sputtering target is obtained by machining the oxide sintered body according to any one of the first to seventh embodiments.

In a ninth embodiment of the present invention, an amorphous oxide semiconductor thin film that is obtained by film deposition on a substrate by using the sputtering target according to the eighth embodiment by sputtering, followed by heating.

In a tenth embodiment of the present invention, an amorphous oxide semiconductor thin film which contains indium and gallium as oxides, contains nitrogen but does not contain zinc and in which a gallium content is 0.20 or more and 0.60 or less in terms of Ga/(In+Ga) atomic ratio, a density of nitrogen is 1×10¹⁸ atoms/cm³ or more, and a carrier mobility is 10 cm² V⁻¹ sec⁻¹ or more.

In an eleventh embodiment of the present invention, a gallium content is 0.20 or more and 0.60 or less in terms of Ga/(In+Ga) atomic ratio in the amorphous oxide semiconductor thin film according to the tenth embodiment.

In a twelfth embodiment of the present invention, a carrier density is 3×10¹⁸ cm⁻³ or less in the amorphous oxide semiconductor thin film according to any one of the ninth to eleventh embodiments.

In a thirteenth embodiment of the present invention, a carrier mobility is 20 cm² V⁻¹ sec⁻¹ or more in the amorphous oxide semiconductor thin film according to any one of the ninth to eleventh embodiments.

### Effects of the Invention

The oxide sintered body of the present invention which contains indium and gallium as oxides, and contains nitrogen, but does not contain zinc is also able to contain nitrogen in the amorphous oxide semiconductor thin film of the present invention that is obtained by depositing a film by sputtering and then subjecting the film to a heat treatment, for example, when being used as a sputtering target. Since the amorphous oxide semiconductor thin film is free of microcrystals and the like and has sufficient amorphous properties because of the effect of predetermined amounts of gallium and nitrogen in the thin film, the thin film can be patterned into a desired shape by wet etching. This effect also allows the amorphous oxide semiconductor thin film of the present invention to have a low carrier density and a high carrier mobility. The amorphous oxide semiconductor thin film of the present invention thus can be used as a channel layer in TFTs. Therefore, the amorphous oxide semiconductor thin film according to the present invention obtained by using the oxide sintered body and target of the present invention is industrially very useful together with these.

### PREFERRED MODE FOR CARRYING OUT THE INVENTION

An oxide sintered body, a sputtering target, and an amorphous oxide thin film obtained using the sputtering target of the present invention will be described below in detail.

The oxide sintered body of the present invention is an oxide sintered body which contains indium and gallium as oxides, and contains nitrogen, but does not contain zinc.

The gallium content, in terms of Ga/(In+Ga) atomic ratio, is 0.20 or more and 0.60 or less and preferably 0.20 or more and 0.35 or less. Gallium has an effect of increasing the crystallization temperature of the amorphous oxide semiconductor thin film of the present invention. Gallium also has an effect of reducing the oxygen loss in the amorphous oxide semiconductor thin film of the present invention because gallium has a high bonding strength with oxygen. Gallium also has an effect of reducing the oxygen loss in the amorphous oxide semiconductor thin film of the present invention because gallium has a high bonding strength with oxygen. When the gallium content is less than 0.20 in terms of Ga/(In+Ga) atomic ratio, these effects are not sufficiently obtained. When the gallium content is more than 0.60 in terms of Ga/(In+Ga) atomic ratio, the carrier mobility is not high enough as an oxide semiconductor thin film because gallium is excessive.

The oxide sintered body used in the present invention contains nitrogen in addition to indium and gallium in the composition ranges defined above. The density of nitrogen is preferably 1×10¹⁹ atoms/cm³ or more. Nitrogen is not contained in the amorphous oxide semiconductor thin film to be obtained in an amount enough to obtain a carrier density lowering effect when the density of nitrogen in the oxide sintered body is less than 1×10¹⁹ atoms/cm³. Incidentally, the density of nitrogen is preferably measured by dynamic-secondary ion mass spectrometry (D-SIMS).

The oxide sintered body of the present invention does not contain zinc. When containing zinc, the sintering temperature is forced to be lowered since the volatilization of zinc begins before the temperature at which the sintering proceeds is achieved. A decrease in sintering temperature hinders the dissolution of nitrogen in the oxide sintered body as well as makes densification of the oxide sintered body difficult.

### 1. Structure of Oxide Sintered Body

It is preferred that the oxide sintered body of the present invention is composed mainly of an In₂O₃ phase having a bixbyite-type structure. Here, it is preferred that gallium is dissolved in the In₂O₃ phase. Gallium substitutes for indium, which is a trivalent cation, at its lattice positions. It is not preferred that gallium is not dissolved in the In₂O₃ phase but forms a Ga₂O₃ phase having a β-Ga₂O₃-type structure because of unsuccessful sintering or the like. Since the Ga₂O₃ phase has low conductivity, abnormal discharge arises.

It is preferred that nitrogen is substitutionally dissolved in the lattice positions of oxygen, which is a divalent anion, in the In₂O₃ phase taking a bixbyite structure. Incidentally, nitrogen may be present at the interstitial location, grain boundary, or the like in the In₂O₃ phase. As described below, the oxide sintered body is exposed to an oxidizing atmosphere at a temperature of 1300° C. or higher in the sintering process, and thus it is not considered that a great amount of nitrogen can be present at the location described above so that the effect of deteriorating the properties of the oxide sintered body or amorphous oxide semiconductor thin film to be formed of the present invention is a concern.

The oxide sintered body used in the present invention is composed mainly of an In₂O₃ phase having a bixbyite-type structure and a GaInO₃ phase having a β-Ga₂O₃-type structure. The oxide sintered body may include a small amount of (Ga, In)₂O₃ phase in addition to these phases. Here, it is preferred that gallium be dissolved in the In₂O₃ phase, or gallium make up the GaInO₃ phase and the (Ga, In)₂O₃ phase. When gallium, which is basically a trivalent cation, is dissolved in the In₂O₃ phase, gallium substitutes for indium, which is also a trivalent cation, at its lattice positions. When gallium makes up the GaInO₃ phase and the (Ga, In)₂O₃ phase, Ga basically occupies original lattice positions, but Ga may be slightly dissolved to substitute for In at the lattice positions as defects. In addition, it is not preferred that gallium be less dissolved in the In₂O₃ phase, or that the GaInO₃ phase having a β-Ga₂O₃-type structure and the (Ga, In)₂O₃ phase be unlikely to be formed because of unsuccessful sintering or the like, and as a result, a Ga₂O₃ phase having a β-Ga₂O₃-type structure be formed. Since the Ga₂O₃ phase has low conductivity, abnormal discharge arises.

The oxide sintered body used in the present invention is composed mainly of the GaInO₃ phase having a β-Ga₂O₃-type structure and may further include a small amount of the (Ga, In)₂O₃ phase. Crystal grains in these phases preferably have a mean particle size of 5 μm or less. Since the crystal grains in these phases are less likely to be ejected by sputtering than crystal grains in the In₂O₃ phase having a bixbyite-type structure, the crystal grains remaining not ejected may cause nodule formation, resulting in arcing.

The oxide sintered body used in the present invention is composed mainly of the In₂O₃ phase having a bixbyite-type structure and the GaInO₃ phase having a β-Ga₂O₃-type structure and may further include a small amount of the (Ga, In)₂O₃ phase. In particular, the oxide sintered body preferably includes the GaInO₃ phase having a β-Ga₂O₃-type structure so that the X-ray diffraction peak intensity ratio defined by formula 1 below is in the range of from 30% or more to 98% or less.

100×I[GaInO₃ phase(−111)]/{I[In₂O₃ phase(400)]+I[GaInO₃ phase(−111)]}[%] Formula 1

(wherein I[In₂O₃ phase (400)] represents a (400) peak intensity of the In₂O₃ phase having a bixbyite-type structure, and I[GaInO₃ phase (−111)] represents a (−111) peak intensity of the complex oxide β-GaInO₃ phase having a β-Ga₂O₃-type structure.)

Incidentally, nitrogen may be contained in the GaInO₃ phase having a β-Ga₂O₃-type structure and the (Ga, In)₂O₃ phase. As described below, it is more preferred to use a gallium nitride powder as a raw material for the oxide sintered body of the present invention, but it is preferred that the oxide sintered body is substantially free of a GaN phase having a wurtzite-type structure in that case. The term “to be substantially free of” means that the weight ratio of the GaN phase having a wurtzite-type structure to the entire formed phases is 5% or less, and the weight ratio is more preferably 3% or less, even more preferably 1% or less, and even more preferably 0%. Incidentally, the weight ratio can be determined by Rietveld analysis through X-ray diffraction measurement. Incidentally, the GaN phase having a wurtzite-type structure is not a problem for the film deposition by direct current sputtering when the weight ratio thereof to the entire formed phases is 5% or less.

### 2. Method for Producing Oxide Sintered Body

The oxide sintered body of the present invention uses an oxide powder consisting of an indium oxide powder and a gallium oxide powder and a nitride powder consisting of a gallium nitride powder, an indium nitride powder, or a powder mixed from these as raw material powders. Gallium nitride powder is more preferable as the nitride powder since it has a higher temperature at which nitrogen is dissociated than the indium nitride powder.

In the process for producing the oxide sintered body of the present invention, these raw material powders are mixed and then compacted, and the compact is sintered by ordinary-pressure sintering. The formed phases in the structure of the oxide sintered body of the present invention strongly depend on the conditions in each step for producing the oxide sintered body, for example, the particle size of the raw material powders, the mixing conditions, and the sintering conditions.

The respective crystal grains of the GaInO₃ phase and the (Ga, In)₂O₃ phase having a β-Ga₂O₃-type structure which constitute the oxide sintered body of the present invention other than the In₂O₃ phase having a bixbyite-type structure are controlled to have a mean particle size of 5 μm or less. Because of this, the mean particle size of the raw material powders is preferably 1.5 μm or less, and more preferably 1.0 μm or less. In particular, the mean particle size of the respective raw material powders is preferably 1.0 μm or less in order to suppress the formation of the (Ga, In)₂O₃ phase which may cause a decrease in deposition rate as much as possible when being formed in a great amount.

Indium oxide powder is a raw material for ITO (indium tin oxide), and fine indium oxide powder having good sintering properties has been developed along with improvements in ITO. Since indium oxide powder has been continuously used in large quantities as a raw material for ITO, raw material powder having a mean particle size of 0.8 μm or less is available these days. However, since the amount of gallium oxide powder used is still smaller than that of indium oxide powder used, it is difficult to obtain raw material powder having a mean particle size of 1.0 μm or less for gallium oxide powder. Therefore, when only coarse gallium oxide powder is available, the powder needs to be pulverized into particles having a mean particle size of 1.0 μm or less. It is the same for the gallium nitride powder, the indium nitride powder, or the powder mixed from these.

The weight ratio of the gallium nitride powder (hereinafter, referred to as the gallium nitride powder weight ratio) to the total amount of the gallium oxide powder and the gallium nitride powder in the raw material powders is preferably over 0 and 0.60 or less. It is difficult to compact or sinter the oxide sintered body when the weight ratio is more than 0.60, and the density of the oxide sintered body is significantly lowered when the weight ratio is 0.70.

In the process for sintering the oxide sintered body of the present invention, ordinary-pressure sintering is preferably employed. Ordinary-pressure sintering is a simple and industrially advantageous method, and is also an economically preferable means.

When ordinary-pressure sintering is used, a compact is first produced as described above. Raw material powders are placed in a resin pot and mixed with a binder (for example, PVA) and the like by wet ball milling or the like. The oxide sintered body used in the present invention includes the In₂O₃ phase having a bixbyite-type structure and the GaInO₃ phase having a β-Ga₂O₃-type structure and may further include the (Ga, In)₂O₃ phase. The crystal grains in these phases are preferably controlled to have a mean particle size of 5 μm or less and are finely dispersed. It is also preferred to suppress formation of the (Ga, In)₂O₃ phase as much as possible. In addition, other than this phase, it is necessary to avoid formation of the Ga₂O₃ phase having a β-Ga₂O₃-type structure, which is a cause of arcing. In order to satisfy these requirements, the ball mill mixing is preferably performed for 18 hours or longer. At this time, hard ZrO₂ balls may be used as mixing balls. After mixing, the slurry is taken out, filtrated, dried, and granulated. Subsequently, the resultant granulated material is compacted under a pressure of about 9.8 MPa (0.1 ton/cm²) to 294 MPa (3 ton/cm²) by cold isostatic pressing to form a compact.

The sintering process by ordinary-pressure sintering is preferably preformed in an atmosphere containing oxygen. The volume fraction of oxygen in the atmosphere is preferably over 20%. In particular, when the volume fraction of oxygen is over 20%, the oxide sintered body is further densified. An excessive amount of oxygen in the atmosphere causes the surface of the compact to undergo sintering in advance during the early stage of sintering. Subsequently, sintering proceeds while the inside of the compact is reduced, and a highly dense oxide sintered body is finally obtained. In the process in which sintering proceeds in the inside of the compact, the nitrogen which is dissociated from gallium nitride and/or indium nitride of the raw material powder is substitutionally dissolved in the lattice positions of oxygen, which is a divalent anion, in the In₂O₃ phase having a bixbyite-type structure. Incidentally, when a GaInO₃ phase having a β-Ga₂O₃-type structure or a GaInO₃ phase having a β-Ga₂O₃-type structure and a (Ga, In)₂O₃ phase are formed other than the In₂O₃ phase, the nitrogen may be substitutionally dissolved in the lattice positions of oxygen, which is a divalent anion, in these phases.

In an atmosphere free of oxygen, the surface of the compact does not undergo sintering and as a result, densification of the sintered body does not proceed. If oxygen is absent, indium oxide decomposes particularly at about 900° C. to 1000° C. to form metal indium, which makes it difficult to obtain a desired oxide sintered body.

The temperature range of ordinary-pressure sintering is from 1300 to 1550° C., and more preferably sintering is performed at 1350 to 1450° C. in an atmosphere obtained by introducing oxygen gas into air in the sintering furnace. The sintering time is preferably 10 to 30 hours and more preferably 15 to 25 hours.

When the sintering temperature is in the above range, and an oxide powder consisting of an indium oxide powder and a gallium oxide powder and a nitride powder consisting of a gallium nitride powder, an indium nitride powder, or a powder as mixture of these, that are controlled to have a mean particle size of 1.0 μm or less are used as raw material powders, it is possible to obtain an oxide sintered body which is composed mainly of the In₂O₃ phase having a bixbyite-type structure and a GaInO₃ phase having a β-Ga₂O₃-type structure and contains nitrogen and in which the formation of the GaInO₃ phase having a β-Ga₂O₃-type structure and the (Ga, In)₂O₃ phase is suppressed as much as possible.

At a sintering temperature lower than 1300° C., the sintering reaction does not proceed well. On the other hand, at a sintering temperature higher than 1550° C., densification does not proceed while a member of the sintering furnace reacts with the oxide sintered body. As a result, a desired oxide sintered body is not obtained. The sintering temperature of the oxide sintered body of the present invention is preferably 1450° C. or lower. This is because formation of the (Ga, In)₂O₃ phase may become significant in the temperature region of about 1500° C.

The temperature elevation rate until the sintering temperature is reached is preferably in the range of 0.2 to 5° C./min in order to cause debinding without forming cracks in the sintered body. As long as the temperature elevation rate is this range, the temperature may be increased to the sintering temperature in a combination of different temperature elevation rates as desired. During the temperature elevation process, a particular temperature may be maintained for a certain time in order for debinding and sintering to proceed. After sintering, oxygen introduction is stopped before cooling. The temperature is preferably decreased to 1000° C. at a temperature drop rate in the range of preferably 0.2 to 5° C./min, and particularly 0.2° C./min or more and less than 1° C./min.

### 3. Target

The oxide sintered body of the present invention is used as a thin film forming target, and it is particularly suitable as a sputtering target. For use as a sputtering target, the oxide sintered body is cut into a predetermined size, the surface thereof is further grinded, and the oxide sintered body is bonded to a backing plate to provide a target. The target preferably has a flat shape, but may have a cylindrical shape. When a cylindrical target is used, it is preferred to suppress particle generation due to target rotation.

It is important to densify the oxide sintered body of the present invention in order to use the oxide sintered body as a sputtering target. However, the density of the oxide sintered body decreases as the gallium content increases, and thus the preferred density is different depending on the gallium content. The density is preferably 6.0 g/cm³ or more when the gallium content is 0.20 or more and 0.60 or less in terms of Ga/(In+Ga) atomic ratio. The generation of nodules is caused at the time of using the oxide sintered body in the film deposition by sputtering in mass production when the density is as low as less than 6.0 g/cm³.

The oxide sintered body of the present invention is also suitable as a target (or also referred to as the tablet) for vapor deposition. It is required to control the density of the oxide sintered body to be lower as compared to the sputtering target in the case of using the oxide sintered body as a target for vapor deposition. Specifically, the density is preferably 3.0 g/cm³ or more and 5.5 g/cm³ or less.

### 4. Oxide Semiconductor Thin Film and Method for Depositing Oxide Semiconductor Thin Film

The amorphous oxide semiconductor thin film of the present invention is obtained as follows: once forming an amorphous oxide thin film on a substrate by sputtering using the sputtering target; and subjecting the amorphous oxide thin film to a heat treatment.

The sputtering target is formed from the oxide sintered body. The structure of the oxide sintered body, namely, the structure that is basically composed of an In₂O₃ phase having a bixbyite-type structure and a GaInO₃ phase having a β-Ga₂O₃-type structure, is important. To obtain the amorphous oxide semiconductor thin film according to the present invention, the amorphous oxide semiconductor thin film needs to have a high crystallization temperature. The crystallization temperature is related to the structure of the oxide sintered body. That is, when the oxide sintered body includes not only an In₂O₃ phase having a bixbyite-type structure but also a GaInO₃ phase having a β-Ga₂O₃-type structure as in the oxide sintered body used in the present invention, the oxide semiconductor thin film formed from this oxide sintered body has a high crystallization temperature, specifically, a crystallization temperature of 300° C. or higher and more preferably 350° C. or higher. That is, the oxide semiconductor thin film is a stable amorphous film. In contrast, when the oxide sintered body includes only an In₂O₃ phase having a bixbyite-type structure, the oxide semiconductor thin film formed from this oxide sintered body has a crystallization temperature as low as about 200° C. to 250° C. and is an unstable amorphous oxide semiconductor thin film. Therefore, a heat treatment at 250° C. or higher or further at 300° C. or higher causes crystallization as described below. In this case, microcrystals are already generated after film deposition, and the oxide sintered body is not amorphous any more, which makes wet-etching patterning difficult. This fact is well known for ordinary ITO (tin-doped indium oxide) transparent conducting films.

Ordinary sputtering is used in the process for depositing the amorphous oxide semiconductor thin film according to the present invention. In particular, direct current (DC) sputtering is industrially advantageous because the thermal effects are minimized during film deposition and high-rate deposition is achieved. To form the oxide semiconductor thin film of the present invention by direct current sputtering, a gas mixture of an inert gas and oxygen, particularly argon and oxygen, is preferably used as a sputtering gas. Sputtering is preferably performed in a chamber of a sputtering apparatus at an internal pressure of 0.1 to 1 Pa, particularly 0.2 to 0.8 Pa.

The substrate is typically a glass substrate and is preferably an alkali-free glass substrate. In addition, any resin sheet and resin film that withstands the above process temperature can be used. The substrate temperature in sputter deposition is preferably 600° C. or lower, and particularly preferably about room temperature or higher and 300° C. or lower.

In the process for forming the amorphous oxide thin film, presputtering can be performed as follows: for example, after evacuation to 2×10⁻⁴ Pa or less, introducing a gas mixture of argon and oxygen until the gas pressure reaches 0.2 to 0.8 Pa; and generating a direct current plasma by applying direct current power so that the direct current power with respect to the area of the target, namely, the direct current power density, is in the range of about 1 to 7 W/cm². It is preferred that, after this presputtering for 5 to 30 minutes, the substrate position be corrected as desired and then sputtering be performed. Incidentally, in sputter deposition in the film deposition process, the direct current power applied is increased without adversely affecting the film quality in order to increase the deposition rate.

The amorphous oxide semiconductor thin film according to the present invention is obtained by depositing the amorphous oxide thin film and then subjecting the amorphous oxide thin film to a heat treatment. In an example method until the heat treatment, an amorphous oxide thin film is once formed at a low temperature, for example, near room temperature, and a heat treatment is then performed at a temperature lower than the crystallization temperature to obtain an amorphous oxide semiconductor thin film. In another method, the substrate is heated to a temperature lower than the crystallization temperature, preferably to between 100 and 300° C., and an amorphous oxide semiconductor thin film is deposited. Subsequently, a heat treatment may be further performed.

The amorphous oxide semiconductor thin film according to the present invention is obtained by once forming the amorphous oxide thin film and then subjecting the amorphous oxide thin film to a heat treatment. The heat treatment is performed in an oxidizing atmosphere at a temperature lower than the crystallization temperature. The oxidizing atmosphere is preferably an atmosphere containing oxygen, ozone, water vapor, nitrogen oxide, or the like. The temperature for heat treatment is 250 to 600° C., preferably 300 to 550° C., and more preferably 350 to 500° C. The time for heat treatment, namely, the time during which the temperature for heat treatment is maintained is preferably 1 to 120 minutes and more preferably 5 to 60 minutes.

The composition of indium and gallium in the amorphous thin film and the crystalline oxide semiconductor thin film substantially corresponds to the composition thereof in the oxide sintered body of the present invention. That is, the oxide semiconductor thin film contains indium and gallium as oxides and further contains nitrogen. The gallium content is 0.20 or more and 0.60 or less and preferably 0.20 or more and 0.35 or less in terms of Ga/(In+Ga) atomic ratio.

The density of nitrogen the amorphous oxide semiconductor thin film is preferably 1×10¹⁸ atoms/cm³ or more in the same manner as in the oxide sintered body of the present invention.

The amorphous oxide semiconductor thin film of the present invention is obtained by film deposition using, as a sputtering target or the like, an oxide sintered body having the composition and structure controlled as described above, followed by a heat treatment under the above appropriate conditions. Through this process, the carrier density decreases to less than 3×10¹⁸ cm⁻³, more preferably the carrier density decreases to 1×10¹⁸ cm⁻³ or less, particularly preferably to 8×10¹⁷ cm⁻³ or less. As represented by an amorphous oxide semiconductor thin film that is composed of indium, gallium, and zinc and described in Non-Patent Document 1, an amorphous oxide semiconductor thin film containing indium in a great amount is in a degenerate state when the carrier density is 4×10¹⁸ cm⁻³ or more. A TFT including such an amorphous oxide semiconductor thin film as a channel layer thus does not exhibit normally-off characteristics. Therefore, the amorphous oxide semiconductor thin film according to the present invention is advantageous in that the carrier density is controlled so that the TFT exhibits normally-off characteristics. In addition, the carrier mobility is 10 cm² V⁻¹ sec⁻¹ or more and more preferably 20 cm² V⁻¹ sec⁻¹ or more.

The amorphous oxide semiconductor thin film of the present invention is subjected to micromachining, which is required in applications such as TFTs, by wet etching or dry etching. In general, an amorphous oxide thin film may be once formed at an appropriate substrate temperature selected from temperatures lower than the crystallization temperature, for example, temperatures from room temperature to 300° C., and then the amorphous oxide thin film may be micromachined by wet etching. Most weak acids can be used as an etchant, but a weak acid composed mainly of oxalic acid or hydrochloric acid is preferably used. For example, commercial products, such as ITO-06N available from Kanto Chemical Co., Inc., can be used. Dry etching may be selected depending on the configuration of TFTs.

Although the thickness of the amorphous oxide semiconductor thin film of the present invention is not limited, the thickness is 10 to 500 nm, preferably 20 to 300 nm, and more preferably 30 to 100 nm. When the thickness is less than 10 nm, unfavorable crystallinity is obtained, and as a result, a high carrier mobility is not achieved. When the film thickness is more than 500 nm, it is disadvantageous in that a problem associated with productivity arises.

In addition, the amorphous oxide semiconductor thin film of the present invention has an average transmittance in the visible region (400 to 800 nm) of preferably 80% or more, more preferably 85% or more, and even more preferably 90% or more. When applying the amorphous oxide semiconductor thin film to a transparent TFT, the light extraction efficiency by a liquid crystal element, an organic EL element, and the like as a transparent display device decreases when the average transmittance is less than 80%.

The amorphous oxide semiconductor thin film of the present invention hardly absorbs light in the visible region but has high transmittance. The a-IGZO film described in Patent Document 1 greatly absorbs light particularly on the short wavelength side of the visible region since it contains zinc. In contrast, the amorphous oxide semiconductor thin film of the present invention hardly absorbs light particularly on the short wavelength side of the visible region since it does not contain zinc, and for example, the extinction coefficient thereof at a wavelength of 400 nm is 0.05 or less. Therefore, the oxide semiconductor thin film of the present invention has high transmittance to blue light near a wavelength of 400 nm and increases the color development of a liquid crystal element, an organic EL element, and the like, and thus it is suitable as a material for the channel layer in the TFT of these.

### EXAMPLES

A more detailed description is provided below by way of

Examples of the present invention, but the present invention is not limited by these Examples.

### <Evaluation of Oxide Sintered Body>

The composition of the metal elements in the obtained oxide sintered body was determined by ICP emission spectroscopy. In addition, the amount of nitrogen in the sintered body was measured by dynamic-secondary ion mass spectrometry (D-SIMS). The formed phases were identified by a powder method with an X-ray diffractometer (available from Philips) using rejects of the obtained oxide sintered body.

### <Evaluation of Basic Properties of Oxide Thin Film>

The composition of the obtained oxide thin film was determined by ICP emission spectrometry. The thickness of the oxide thin film was determined with a surface profilometer (available from KLA-Tencor Corporation). The deposition rate was calculated from the film thickness and the film deposition time. The carrier density and mobility of the oxide thin film were determined with a Hall-effect measurement apparatus (available from TOYO Corporation). The formed phases in the film were identified by X-ray diffraction measurement.

### Examples 1-7

An indium oxide powder, a gallium oxide powder, and a gallium nitride powder were prepared as raw material powders so that each powder has a mean particle size of 1.5 μm or less. These raw material powders were prepared so as to obtain the Ga/(In+Ga) atomic ratio and the weight ratio of the gallium oxide powder and the gallium nitride powder shown in Table 1. The raw material powders were placed in a resin pot together with water and mixed by wet ball milling. In this case, hard ZrO₂ balls were used and the mixing time was 18 hours. After mixing, slurry was taken out, filtrated, dried, and granulated. The granulated material was compacted by cold isostatic pressing under a pressure of 3 ton/cm².

Next, the compact was sintered as described below. The compact was sintered at a sintering temperature of between 1350 and 1450° C. for 20 hours in an atmosphere obtained by introducing oxygen into air in a sintering furnace at a rate of 5 L/min per 0.1 m³ furnace volume. At this time, the temperature was increased by 1° C./min, oxygen introduction was stopped during cooling after sintering, and the temperature was decreased to 1000° C. by 10° C./min.

The composition of the obtained oxide sintered body was analyzed by ICP emission spectrometry. As a result, it was confirmed that the proportion of the metal elements substantially the same as the composition prepared at the time of mixing raw material powders in all Examples. The amount of nitrogen in the oxide sintered body was from 6.1×10¹⁹ to 4.3×10²⁰ atoms/cm³ as shown in Table 1.

Next, the phase identification of the oxide sintered body was performed by X-ray diffraction measurement, in Examples 1 to 7, only the diffraction peaks attributed to the In₂O₃ phase having a bixbyite-type structure and the GaInO₃ phase having a β-Ga₂O₃-type structure and the (Ga, In)₂O₃ phase were confirmed, but the GaN phase having a wurtzite-type structure or the Ga₂O₃ phase having a β-Ga₂O₃-type structure were not confirmed. When the oxide sintered body includes a GaInO₃ phase having a β-Ga₂O₃-type structure, the X-ray diffraction peak intensity ratio of the GaInO₃ phase having a β-Ga₂O₃-type structure defined by formula 1 below is shown in Table 1.

100×I[GaInO₃ phase(111)]/{I[In₂O₃ phase(400)]+I[GaInO₃ phase(111)]}[%] Formula 1

TABLE 1

| | | | | Density | | | | |
|---|---|---|---|---|---|---|---|---|
| | | | | of | | GaInO₃(111) | | |
| | Ga/(In + Ga) | GaN/ | Sintering | sintered | Density of | Peak | | |
| | Atomic | (Ga₂O₃ + GaN) | temperature | body | Nitrogen | intensity | GaN | Ga₂O₃ |
| | ratio | Weight ratio | (° C.) | (g/cm³) | (atoms/cm³) | ratio | phase | phase |
| Example1 | 0.20 | 0.01 | 1400 | 6.92 | 6.1 × 10¹⁹ | 30 | Absence | Absence |
| Example2 | 0.25 | 0.60 | 1400 | 6.54 | 4.3 × 10²⁰ | 48 | Absence | Absence |
| Example3 | 0.30 | 0.20 | 1400 | 6.67 | 1.7 × 10²⁰ | 50 | Absence | Absence |
| Example4 | 0.35 | 0.01 | 1400 | 6.60 | 9.8 × 10¹⁹ | 71 | Absence | Absence |
| Example5 | 0.45 | 0.01 | 1400 | 6.41 | 1.1 × 10²⁰ | 82 | Absence | Absence |
| Example6 | 0.50 | 0.01 | 1400 | 6.32 | 1.4 × 10²⁰ | 85 | Absence | Absence |
| Example7 | 0.60 | 0.01 | 1400 | 6.15 | 2.2 × 10²⁰ | 98 | Absence | Absence |

In addition, the density of the oxide sintered body was measured to obtain a result of from 6.15 to 6.92 g/cm³.

The oxide sintered body was machined to a size of 152 mm in diameter and 5 mm in thickness. The sputtering surface was grinded with a cup grinding wheel so that the maximum height Rz was 3.0 μm or less. The machined oxide sintered body was bonded to an oxygen-free copper backing plate by using metal indium to provide a sputtering target.

Film deposition by direct current sputtering was performed at the substrate temperatures described in Table 2 by using the sputtering targets of Examples and an alkali-free glass substrate (Corning Eagle XG). The sputtering target was attached to a cathode of a direct current magnetron sputtering apparatus (available from Tokki Corporation) having a direct current power supply with no arcing control function. At this time, the target-substrate (holder) distance was fixed at 60 mm. After evacuation to 2×10⁻⁴ Pa or less, a gas mixture of argon and oxygen was introduced at an appropriate oxygen ratio, which depends on the gallium content and zinc content in each target. The gas pressure was controlled to 0.6 Pa. A direct current plasma was generated by applying a direct current power of 300 W (1.64 W/cm²). After presputtering for 10 minutes, the substrate was placed directly above the sputtering target, namely, in the stationary opposing position, and an oxide thin film having a thickness of 50 nm was deposited The composition of the obtained oxide thin film was confirmed to be substantially the same as that of the target.

The deposited oxide thin film was heated at between 350 and 500° C. for 30 to 60 minutes in oxygen as described in Table 2. The crystallinity of the heated oxide thin film was examined by X-ray diffraction measurement. As a result, the heated oxide thin films of Examples and Comparative Examples were all amorphous. In addition, for crystallized oxide semiconductor thin films, the crystalline phases in the oxide semiconductor thin films were identified. The Hall-effect measurement was performed on the oxide semiconductor thin films of Examples and Comparative Examples to obtain the carrier density and the carrier mobility. The obtained evaluation results are summarized in Table 2.

TABLE 2

| | Ga/ | Temperature | | | | | Carrier |
|---|---|---|---|---|---|---|---|
| | (In + Ga) | for heat | Film | Crystal | Density of | Carrier | mobility |
| | Atomic | treatment | thickness | structure of | Nitrogen | density | (cm²/ |
| | ratio | (° C.) | (nm) | thin film | (atoms/cm³) | (×10¹⁷ cm⁻³) | V⁻¹sec⁻¹) |
| Example1 | 0.20 | 350 | 50 | Amorphous | 2.7 × 10¹⁸ | 22 | 27.1 |
| Example2 | 0.25 | 350 | 50 | Amorphous | 4.4 × 10¹⁸ | 10 | 25.8 |
| Example3 | 0.30 | 350 | 50 | Amorphous | 3.4 × 10¹⁸ | 6.2 | 23.9 |
| Example4 | 0.35 | 350 | 50 | Amorphous | 1.2 × 10¹⁸ | 2.5 | 20.6 |
| Example5 | 0.45 | 500 | 50 | Amorphous | 3.8 × 10¹⁸ | 0.095 | 13.2 |
| Example6 | 0.50 | 500 | 50 | Amorphous | 6.2 × 10¹⁸ | 0.063 | 12.3 |
| Example7 | 0.60 | 500 | 50 | Amorphous | 3.3 × 10¹⁸ | 0.021 | 10.3 |

### Comparative Example 1-5

The same raw material powders as those in Examples 1 to 7 were prepared so as to have the Ga/(In+Ga) atomic ratio and the weight ratio of the gallium oxide powder and the gallium nitride powder shown in Table 3, and the oxide sintered body was prepared by the same method as in Examples 1 to 7.

The composition analysis of the obtained oxide sintered body was performed by ICP emission spectroscopy, and it was confirmed in any of the present Comparative Examples that the composition of the metal elements is substantially the same as the composition prepared at the time of mixing the raw material powders. In addition, the amount of nitrogen in the oxide sintered body was from 5.5×10¹⁸ to 6.4×10²⁰ atoms/cm³ as shown in Table 3.

TABLE 3

| | | GaN/ | | Density | Density | GaInO₃ | | |
|---|---|---|---|---|---|---|---|---|
| | Ga/ | (Ga₂O₃ + | | of | of | (111) | | |
| | (In + Ga) | GaN) | Sintering | sintered | Nitrogen | Peak | | |
| | Atomic | Weight | temperature | body | (atoms/ | intensity | GaN | Ga₂O₃ |
| | ratio | ratio | (° C.) | (g/cm³) | cm³) | ratio | phase | phase |
| Comparative | 0.001 | 0.60 | 1450 | 6.90 | 5.5 × 10¹⁸ | — | Absence | Absence |
| Example1 | | | | | | | | |
| Comparative | 0.05 | 0.70 | 1400 | 6.04 | 3.5 × 10²⁰ | — | Presence | Absence |
| Example2 | | | | | | | | |
| Comparative | 0.10 | 0.02 | 1400 | 7.07 | 6.8 × 10¹⁹ | 11 | Absence | Absence |
| Example3 | | | | | | | | |
| Comparative | 0.15 | 0.01 | 1400 | 6.95 | 3.3 × 10¹⁹ | 22 | Absence | Absence |
| Example4 | | | | | | | | |
| Comparative | 0.65 | 0.10 | 1450 | 6.12 | 6.4 × 10²⁰ | 119 | Absence | Absence |
| Example5 | | | | | | | | |

Next, the phase identification of the oxide sintered body was performed by the X-ray diffraction measurement. In Comparative Example 1, only the diffraction peak attributed to the In₂O₃ phase having a bixbyite-type structure was confirmed. In Comparative Example 2, the diffraction peak attributed to the GaN phase having a wurtzite-type structure was also confirmed in addition to the diffraction peak attributed to the In₂O₃ phase having a bixbyite-type structure, and the weight ratio of the GaN phase to the entire phases by Rietveld analysis was more than 5%. In Comparative Examples 3 to 5, the diffraction peaks attributed to the In₂O₃ phase having a bixbyite-type structure and the GaInO₃ phase having a β-Ga₂O₃-type structure were confirmed.

A sputtering target was obtained by machining the oxide sintered body in the same manner as in Examples 1 to 7. An oxide thin film having a thickness of 50 nm was deposited on an alkali-free glass substrate (Corning #7059) at room temperature by using the obtained sputtering target under the same sputtering conditions as in Examples 1 to 7.

The obtained composition of the oxide thin film was confirmed to be substantially the same as that of the target. In addition, the oxide thin film was confirmed to be amorphous as a result of the X-ray diffraction measurement. The obtained amorphous oxide thin film was subjected to a heat treatment for 30 minutes at 250 to 500° C. in air. The obtained oxide semiconductor thin films were all amorphous. The Hall effect measurement was performed on the obtained oxide semiconductor thin film to obtain the carrier density and the carrier mobility. The obtained evaluation results are summarized in Table 4.

TABLE 4

| | Ga/ | Temperature | | | | | Carrier |
|---|---|---|---|---|---|---|---|
| | (In + Ga) | for heat | Film | Crystal | Density of | Carrier | mobility |
| | Atomic | treatment | thickness | structure of | Nitrogen | density | (cm²/ |
| | ratio | (° C.) | (nm) | thin film | (atoms/cm³) | (×10¹⁷ cm⁻³) | V⁻¹sec⁻¹) |
| Comparative | 0.001 | 250 | 50 | Amorphous | 7.3 × 10¹⁷ | 84 | 17.8 |
| Example1 | | | | | | | |
| Comparative | 0.05 | 250 | 50 | Amorphous | 3.6 × 10¹⁸ | 62 | 22.2 |
| Example2 | | | | | | | |
| Comparative | 0.10 | 250 | 50 | Amorphous | 2.6 × 10¹⁸ | 56 | 23.7 |
| Example3 | | | | | | | |
| Comparative | 0.15 | 250 | 50 | Amorphous | 1.5 × 10¹⁸ | 44 | 24.6 |
| Example4 | | | | | | | |
| Comparative | 0.65 | 500 | 50 | Amorphous | 3.6 × 10¹⁸ | 0.012 | 4.1 |
| Example5 | | | | | | | |

### [Evaluation]

From the results of Table 1, in Examples 1 to 7, the oxide sintered bodies are a oxide sintered body which contains indium and gallium as oxides, contains nitrogen, but does not contain zinc, and has the properties of a oxide sintered body so that the gallium content is controlled to 0.20 or more and 0.60 or less in terms of Ga/(In+Ga) atomic ratio. The gallium nitride powder is blended in the oxide sintered body of Examples 1 to 7 so as to have the weight ratio thereof of from 0.01 to 0.60, and as a result, the density of nitrogen in the oxide sintered body is 1×10¹⁹ atoms/cm³ or more. It was found that the obtained sintered body has a high density of sintered body of 6.0 g/cm³ or more in Examples 1 to 7 in which the gallium content is from 0.20 to 0.60 in terms of Ga/(In+Ga) atomic ratio.

The results of Table 2 also indicate that, the amorphous oxide semiconductor thin films are composed of indium, gallium, and nitrogen. The properties of the oxide semiconductor thin films are controlled so that the gallium content is 0.20 or more and 0.60 or less in terms of Ga/(In+Ga) atomic ratio. In addition, the oxide semiconductor thin films of Examples have a carrier density of 3×10¹⁸ cm³ or less and a carrier mobility of 10 cm² V⁻¹ sec⁻¹ or more, and in particular, the oxide semiconductor thin film having a gallium content of from 0.20 or more and 0.35 or less in terms of Ga/(In+Ga) atomic ratio exhibits good properties, a carrier mobility of 20 cm² V⁻¹ sec⁻¹ or more.

In Table 3, in the oxide sintered body in which the gallium content is 0.001 in terms of Ga/(In+Ga) atomic ratio of Comparative Example 1, the gallium nitride powder is blended in the raw material powders so as to have a weight ratio of 0.60, but the density of nitrogen is less than 1×10¹⁹ atoms/cm³. Furthermore, in the oxide sintered body in which the gallium content is 0.05 in terms of Ga/(In+Ga) atomic ratio of Comparative Example 2, the gallium nitride powder is blended in the raw material powders so as to have a weight ratio of 0.70, as a result, the density of the sintered body is only 6.04 g/cm³, the oxide sintered body is not composed only of the In₂O₃ phase having a bixbyite-type structure, but it includes the GaN phase having a wurtzite-type structure, which causes arcing in the film deposition by sputtering.

Furthermore, from Table 4, the gallium content in Comparative Examples 1 to 4 is lower than 0.20 so as not to be in the range of the present invention, and thus the carrier density is more than 3×10¹⁸ cm³. In addition, the oxide semiconductor thin film of Comparative Example 5 has an excessive gallium content of 0.65, and thus the carrier mobility thereof is less than 10 cm² V⁻¹ sec⁻¹.

1. An oxide sintered body comprising indium and gallium as oxides, wherein
a gallium content is 0.20 or more and 0.60 or less in terms of Ga/(In+Ga) atomic ratio,
the oxide sintered body contains nitrogen but does not contain zinc, and
the oxide sintered body does not substantially include a GaN phase having a wurtzite-type structure.

2. The oxide sintered body according to claim 1, wherein the gallium content is 0.20 or more and 0.35 or less in terms of Ga/(In+Ga) atomic ratio.

3. The oxide sintered body according to claim 1, wherein a density of nitrogen is 1×10¹⁹ atoms/cm³ or more.

4. The oxide sintered body according to claim 1, wherein the oxide sintered body is composed of
an In₂O₃ phase having a bixbyite-type structure,
and a GaInO₃ phase having a β-Ga₂O₃-type structure as a formed phase other than the In₂O₃ phase, or a GaInO₃ phase having a β-Ga₂O₃-type structure and a (Ga, In)₂O₃ phase as a formed phase other than the In₂O₃ phase.

5. The oxide sintered body according to claim 4, wherein an X-ray diffraction peak intensity ratio of a GaInO₃ phase having a β-Ga₂O₃-type structure defined by formula 1 below is in a range of 30% or more and 98% or less.
100×I[GaInO₃ phase(111)]/{I[In₂O₃ phase(400)]+I[GaInO₃ phase(111)]}[%] Formula 1

6. The oxide sintered body according to claim 1, wherein the oxide sintered body does not include a Ga₂O₃ phase having a β-Ga₂O₃-type structure.

7. The oxide sintered body according to claim 1, wherein the oxide sintered body is sintered by ordinary-pressure sintering in an atmosphere having a volume fraction of oxygen over 20%.

8. A sputtering target obtained by machining the oxide sintered body according to claim 1.

9. An amorphous oxide semiconductor thin film obtained by film deposition on a substrate by using the sputtering target according to claim 8 by sputtering, followed by heating.

10. An amorphous oxide semiconductor thin film comprising:
indium and gallium as oxides; and
nitrogen; but
not comprising zinc, wherein
a gallium content is 0.20 or more and 0.60 or less in terms of Ga/(In+Ga) atomic ratio,
a density of nitrogen is 1×10¹⁸ atoms/cm³ or more, and
a carrier mobility is 10 cm² V⁻¹ sec⁻¹ or more.

11. The amorphous oxide semiconductor thin film according to claim 10, wherein the gallium content is 0.20 or more and 0.35 or less in terms of Ga/(In+Ga) atomic ratio.

12. The amorphous oxide semiconductor thin film according to claim 9, wherein a carrier density is 3×10¹⁸ cm⁻³ or less.

13. The amorphous oxide semiconductor thin film according to claim 9, wherein a carrier mobility is 20 cm² V⁻¹ sec⁻¹ or more.

14. The amorphous oxide semiconductor thin film according to claim 10, wherein a carrier density is 3×10¹⁸ cm⁻³ or less.

15. The amorphous oxide semiconductor thin film according to claim 10, wherein a carrier mobility is 20 cm² V⁻¹ sec⁻¹ or more.
